(19) United States
(12) Patent Application Publication
(10) Pub. No.: US 2017/0130127 A1
(43) Pub. Date: May 11, 2017

(54) SEMICONDUCTOR NANOCRYSTALS AND METHODS OF PREPARATION

(71) Applicant: QD VISION, INC., LEXINGTON, MA (US)

(72) Inventors: JUSTIN W. KAMPLAIN, BARTLESVILLE, OK (US); MELANIE BUNDA, NEWTON, MA (US)

(21) Appl. No.: 15/176,065

(22) Filed: Jun. 7, 2016

Related U.S. Application Data
(60) Provisional application No. 62/202,784, filed on Aug. 7, 2015.

(51) Int. Cl. C09K 11/88; H01L 21/02

(52) U.S. Cl. CPC C09K 11/883; H01L 21/02546; H01L 21/0256; H01L 21/02601; B82Y 40/00

(57) ABSTRACT

Semiconductor nanocrystals and methods of making are provided.

This application claims priority to U.S. Provisional Patent Application No. 62/202,784, filed 7 Aug. 2015, which is hereby incorporated herein by reference in its entirety for all purposes.

### FEDERALLY SPONSORED RESEARCH OR DEVELOPMENT

This invention was made with Government support under Contract No. H92222-12-C-0002 awarded by the US Special Operations Command (USSOCOM). The Government has certain rights in the invention.

### TECHNICAL FIELD OF THE INVENTION

The present invention relates to the technical field of nanotechnology, and more particularly to semiconductor nanocrystals and methods for preparing same.

### SUMMARY OF THE INVENTION

In accordance with one aspect of the present invention, there is provided a method for preparing semiconductor nanocrystals comprising contacting an M-precursor compound with an X donor, wherein the X donor is represented by the formula (I):

X(Y(R)₃)₃ (I)

where X is a group V element; Y is Ge, Sn, or Pb; and each R, independently, is alkyl, alkenyl, alkynyl, cycloalkyl, cycloalkenyl, heterocyclyl, aryl, or heteroaryl, wherein each R, independently, is optionally substituted by 1 to 6 substituents independently selected from hydrogen, halo, hydroxy, nitro, cyano, amino, alkyl, cycloalkyl, cycloalkenyl, alkoxy, acyl, thio, thioalkyl, alkenyl, alkynyl, cycloalkenyl, heterocyclyl, aryl, or heteroaryl at a first temperature to form a reaction mixture; and

heating the reaction mixture at a second temperature for at least an hour, wherein the second temperature is the same as or different from the first temperature.

The compound of formula (I) can be tris(trimethylgermyl)nitride; tris(trimethylstannyl)nitride; tris(trimethylplumbyl)nitride; tris(trimethylgermyl)phosphide; tris(trimethylstannyl) phosphide; tris(trimethylplumbyl) phosphide; tris(trimethylgermyl)arsine; tris(trimethylstannyl)arsine; tris(trimethylplumbyl)arsine; tris(trimethylgermyl)stibine; tris(trimethylstannyl)stibine; or tris(trimethylplumbyl)stibine.

In certain embodiments, X can be As. Y can be Ge. Each R, independently, can be alkyl, cycloalkyl, or aryl. Each R, independently, can be unsubstituted alkyl, unsubstituted cycloalkyl, or unsubstituted aryl.

In certain embodiments, M included in the M-precursor includes can be a group III element. M can be In.

In accordance with another aspect of the present invention, there is provided a method for preparing a semiconductor nanocrystal including a core comprising a Group III element and a Group V element and a shell over at least a portion of the core, the method comprising: contacting an M-precursor compound with an X donor, wherein the X donor is represented by the formula (I):

X(Y(R)₃)₃ (I)

in a reaction mixture, where X is a group V element; Y is Ge, Sn, or Pb; and each R, independently, is alkyl, alkenyl, alkynyl, cycloalkyl, cycloalkenyl, heterocyclyl, aryl, or heteroaryl, wherein each R, independently, is optionally substituted by 1 to 6 substituents independently selected from hydrogen, halo, hydroxy, nitro, cyano, amino, alkyl, cycloalkyl, cycloalkenyl, alkoxy, acyl, thio, thioalkyl, alkenyl, alkynyl, cycloalkenyl, heterocyclyl, aryl, or heteroaryl at a first temperature to form a reaction mixture; and

heating the reaction mixture at a second temperature for at least an hour, wherein the second temperature is the same as or different from the first temperature;

isolating cores from the reaction mixture after heating; and

forming at least a first shell over at least a portion of the isolated cores, the shell comprising a semiconductor material.

The compound of formula (I) can be tris(trimethylgermyl)nitride; tris(trimethylstannyl)nitride; tris(trimethylplumbyl)nitride; tris(trimethylgermyl)phosphide; tris(trimethylstannyl) phosphide; tris(trimethylplumbyl) phosphide; tris(trimethylgermyl)arsine; tris(trimethylstannyl)arsine; tris(trimethylplumbyl)arsine; tris(trimethylgermyl)stibine; tris(trimethylstannyl)stibine; or tris(trimethylplumbyl)stibine.

In certain embodiments, X can be As. Y can be Ge. Each R, independently, can be alkyl, cycloalkyl, or aryl. Each R, independently, can be unsubstituted alkyl, unsubstituted cycloalkyl, or unsubstituted aryl.

In certain embodiments, M included in the M-precursor includes can be a group III element. M can be In.

In certain embodiments, the semiconductor material can be a Group II-VI semiconductor. Examples of a Group II-VI semiconductor include, but are not limited to, CdSe, ZnSe, etc. In certain embodiments, ZnSe can be preferred.

In certain embodiments, the method can further comprise forming a second shell over the first shell. The second shell can comprise a semiconductor material. In certain embodiments, a Group II-VI semiconductor can be preferred.

In accordance with another aspect of the present invention, there is provided a method for preparing a semiconductor nanocrystal including a core comprising a Group III element and a Group V element and a shell over at least a portion of the core, the method comprising: contacting an M-precursor compound with an X donor, wherein the X donor is represented by the formula (I):

X(Y(R)₃)₃ (I)

in a reaction mixture, where X is a group V element; Y is Ge, Sn, or Pb; and each R, independently, is alkyl, alkenyl, alkynyl, cycloalkyl, cycloalkenyl, heterocyclyl, aryl, or heteroaryl, wherein each R, independently, is optionally substituted by 1 to 6 substituents independently selected from hydrogen, halo, hydroxy, nitro, cyano, amino, alkyl, cycloalkyl, cycloalkenyl, alkoxy, acyl, thio, thioalkyl, alkenyl, alkynyl, cycloalkenyl, heterocyclyl, aryl, or heteroaryl at a first temperature to form a reaction mixture;

heating the reaction mixture at a second temperature for at least an hour, wherein the second temperature is the same as or different from the first temperature; and

forming at least a first shell over at least a portion of the cores in the reaction mixture, the shell comprising a semiconductor material.

The compound of formula (I) can be tris(trimethylgermyl)nitride; tris(trimethylstannyl)nitride; tris(trimethylplumbyl)nitride; tris(trimethylgermyl)phosphide; tris(trimethylstannyl) phosphide; tris(trimethylplumbyl) phosphide; tris(trimethylgermyl)arsine; tris(trimethylstannyl)arsine; tris(trimethylplumbyl)arsine; tris(trimethylgermyl)stibine; tris(trimethylstannyl)stibine; or tris (trimethylplumbyl) stibine.

In certain embodiments, X can be As. Y can be Ge. Each R, independently, can be alkyl, cycloalkyl, or aryl. Each R, independently, can be unsubstituted alkyl, unsubstituted cycloalkyl, or unsubstituted aryl.

In certain embodiments, M included in the M-precursor includes can be a group III element. M can be In.

In certain embodiments, the semiconductor material can be a Group II-VI semiconductor. Examples of a Group II-VI semiconductor include, but are not limited to, CdSe, ZnSe, etc. In certain embodiments, ZnSe can be preferred.

In certain embodiments, the method can further comprise forming a second shell over the first shell. The second shell can comprise a semiconductor material. In certain embodiments, a Group II-VI semiconductor can be preferred.

In accordance with another aspect of the present invention, there is provided a semiconductor nanocrystal including a core comprising indium arsenide, a first shell comprising zinc selenide, and a second shell comprising a second semiconductor material.

In certain embodiments, the second shell comprises a Group II-VI semiconductor.

In certain embodiments, the second shell comprises cadmium, zinc, and selenium.

The foregoing, and other aspects described herein, all constitute embodiments of the present invention.

It should be appreciated by those persons having ordinary skill in the art(s) to which the present invention relates that any of the features described herein in respect of any particular aspect and/or embodiment of the present invention can be combined with one or more of any of the other features of any other aspects and/or embodiments of the present invention described herein, with modifications as appropriate to ensure compatibility of the combinations. Such combinations are considered to be part of the present invention contemplated by this disclosure.

Additional information concerning the foregoing, and other information useful with the present inventions is provided below.

It is to be understood that both the foregoing general description and the following detailed description are exemplary and explanatory only and are not restrictive of the invention as claimed. Other embodiments will be apparent to those skilled in the art from consideration of the description and drawings, from the claims, and from practice of the invention disclosed herein.

### BRIEF DESCRIPTION OF THE DRAWINGS

In the drawings,

FIGS. 1-6 are graphic depictions of data relating to various examples described in the specification.

For a better understanding of the present invention, together with other advantages and capabilities thereof, reference is made to the following disclosure and appended claims in connection with the above-described drawings.

### DETAILED DESCRIPTION OF THE INVENTION

Various aspects and embodiments of the present inventions will be further described in the following detailed description.

The present invention relates to methods for preparing semiconductor nanocrystals. The present invention further relates to semiconductor nanocrystals.

Semiconductor nanocrystals have size-dependent optical and electronic properties. In particular, the band gap energy of a semiconductor nanocrystal of a particular semiconductor material varies with the diameter of the crystal. Generally, a semiconductor nanocrystal is a member of a population of nanocrystals having a distribution of sizes. When the distribution is centered about a single value and narrow, the population can be described as monodisperse. Monodisperse particles can, for example, have at least 60% of the particles fall within a specified particle size range.

Semiconductor nanocrystals can be a sphere, rod, disk, or other shape.

Semiconductor nanocrystals demonstrate quantum confinement effects in their luminescent properties. A semiconductor nanocrystal is capable of emitting light upon excitation. A semiconductor nanocrystal can be excited by irradiation with an excitation wavelength of light, by electrical excitation, or by other energy transfer.

The emission from a semiconductor nanocrystal can be a narrow Gaussian emission band that can be tuned through the complete wavelength range of the ultraviolet, visible, or infra-red regions of the spectrum by varying the size of the semiconductor nanocrystal, the composition of the semiconductor nanocrystal, or both.

In certain embodiments, the semiconductor nanocrystals of the invention comprise semiconductor nanocrystals that are capable of emitting light with a peak emission wavelength in a range from about 800 nm to about 2 microns upon excitation.

Photoluminescence quantum efficiency (also referred to as quantum efficiency, quantum yield or solution quantum yield) represents the percent of absorbed photons that are reemitted as photons upon excitation by irradiation with an excitation wavelength of light.

A nanocrystal is a nanometer sized particle, e.g., in the size range of up to about 1000 nm In certain embodiments, a nanocrystal can have a size in the range of up to about 100 nm In certain embodiments, a nanocrystal can have a size in the range up to about 20 nm (such as about 1, 2, 3, 4, 5, 6, 7, 8, 9, 10, 11, 12, 13, 14, 15, 16, 17, 18, 19, or 20 nm). In certain embodiments, a nanocrystal can have a size less than 100 Å.

In accordance with one aspect of the present invention, there is provided a method for preparing semiconductor nanocrystals comprising contacting an M-precursor compound with an X donor, wherein the X donor is represented by the formula (I):

X(Y(R)₃)₃ (I)

where X is a group V element; Y is Ge, Sn, or Pb; and each R, independently, is alkyl, alkenyl, alkynyl, cycloalkyl, cycloalkenyl, heterocyclyl, aryl, or heteroaryl, wherein each R, independently, is optionally substituted by 1 to 6 substituents independently selected from hydrogen, halo, hydroxy, nitro, cyano, amino, alkyl, cycloalkyl, cycloalkenyl, alkoxy, acyl, thio, thioalkyl, alkenyl, alkynyl, cycloalkenyl, heterocyclyl, aryl, or heteroaryl at a first temperature to form a reaction mixture; and

heating the reaction mixture at a second temperature for at least an hour, wherein the second temperature is the same as or different from the first temperature.

The compound of formula (I) can be tris(trimethylgermyl)nitride; tris(trimethylstannyl)nitride; tris(trimethylplumbyl)nitride; tris(trimethylgermyl)phosphide; tris(trimethylstannyl) phosphide; tris(trimethylplumbyl) phosphide; tris(trimethylgermyl)arsine; tris(trimethylstannyl)arsine; tris(trimethylplumbyl)arsine; tris(trimethylgermyl)stibine; tris(trimethylstannyl)stibine; or tris(trimethylplumbyl)stibine.

Group V (also referred to herein as Group VA) elements include, for example, nitrogen, phosphorus, arsenic, antimony, and bismuth.

In certain embodiments, X can be As. Y can be Ge. Each R, independently, can be alkyl, cycloalkyl, or aryl. Each R, independently, can be unsubstituted alkyl, unsubstituted cycloalkyl, or unsubstituted aryl.

An X donor can further be included in a solvent before being contacted with an M-precursor. In certain embodiments, a solvent can comprise a coordinating solvent or a weakly coordinating solvent. In certain embodiments, a solvent comprises a non-coordinating solvent. A solvent can also comprise a mixture of solvents

In certain preferred embodiments, M included in the M-precursor includes can be a group III element. In certain embodiments, an M-precursor wherein M includes indium can be more preferred.

Examples of M-precursors include, for example, elements, covalent compounds, ionic compounds, and/or coordination complexes, that serve as a source for the desired metal element(s) in the resulting nanocrystal. For example, a metal precursor can constitute a wide range of substances, including, but not limited to, a metal oxide, a metal carbonate, a metal bicarbonate, a metal sulfate, a metal sulfite, a metal phosphate, metal phosphite, a metal halide, a metal carboxylate, a metal alkoxide, a metal thiolate, a metal amide, a metal imide, a metal alkyl, a metal aryl, other organometallics, a metal coordination complex, a metal solvate, and the like. For example, non-limiting examples of indium precursors include In(III) acetate, In(III) trifluoroacetate, trialkyl indium (InR₃)(wherein R=methyl, ethyl, propyl, butyl, pentyl, hexyl, isopropyl, isobutyl, tert-butyl, etc.); non-limiting examples of gallium precursors include Ga(III) acetate, Ga(III) trifluoroacetate, trialkyl gallium (InR₃)(wherein R=methyl, ethyl, propyl, butyl, pentyl, hexyl, isopropyl, isobutyl, tert-butyl, etc.). Other Group III metal precursors can be readily ascertained by one of ordinary skill in the art.

An M-precursor can further be included in a solvent before being contacted with an X donor. In certain embodiments, a solvent can comprise a coordinating solvent or a weakly coordinating solvent. In certain embodiments, a solvent comprises a non-coordinating solvent. A solvent can also comprise a mixture of solvents

In certain embodiments, the reaction mixture can further include one or more additional solvents.

Examples of solvents include, but are not limited to, octadecene, squalene, methyl myristate, octyl octanoate, hexyl octanoate, and CH₃(CH₂)ₙC(O)O(CH₂)ₘCH₃ wherein n=4-18 and m=1-8, dioctyl ether, and diphenyl ether, and mixtures of one or more solvents. In certain embodiments, a mixture can comprise a mixture, (including but not limited to a eutectic mixture) of biphenyl and diphenyl oxide, including, e.g., DOWTHERM A, available from the Dow Chemical Company. Other high boiling point ethers (e.g., BP>˜200° C.) may also be used. Such ethers (coordinating) can be aromatic ethers, aliphatic ethers or aromatic aliphatic ethers. Examples of additional ethers include, but are not limited to, dihexyl ether, diethyleneglycol dimethyl ether, diethyleneglycol dibutyl ether, triethyleneglycol dimethyl ether, tetraethyleneglycol dimethyl ether, butyl phenyl ether, benzyl phenyl ether, dibenzyl ether, ditolyl ether and isomers thereof. Mixtures of two or more solvents can also be used. Other coordinating solvents can be readily ascertained by one of ordinary skill in the art.

Examples of other non-coordinating solvents that may be useful include, but are not limited to, squalane, octadecane, or any other saturated hydrocarbon molecule. Mixtures of two or more solvents can also be used.

Other solvents for use in the methods taught herein can be readily ascertained by one of ordinary skill in the art.

In certain embodiments, the first temperature is less than 300° C. For example, the first temperature can be in a range from about 80° C. to about 285° C. Other temperatures may be determined to be useful or desirable.

The second temperature can be the same as the first temperature or different. In certain embodiments, for example, the second temperature can be in a range from about 260° C. to about 285° C. Other temperatures may be determined to be useful or desirable.

In certain embodiment, heating at the second temperature can be carried out for up to 2 hours, up to 2.5, hours, up to 3 hours, up to 3.5 hours. Other times within these ranges or outside of these ranges may also be useful.

In accordance with another aspect of the present invention, there is provided a method for preparing a semiconductor nanocrystal including a core comprising a Group III element and a Group V element and a shell over at least a portion of the core, the method comprising: contacting an M-precursor compound with an X donor, wherein the X donor is represented by the formula (I):

X(Y(R)₃)₃ (I)

in a reaction mixture, where X is a group V element; Y is Ge, Sn, or Pb; and each R, independently, is alkyl, alkenyl, alkynyl, cycloalkyl, cycloalkenyl, heterocyclyl, aryl, or heteroaryl, wherein each R, independently, is optionally substituted by 1 to 6 substituents independently selected from hydrogen, halo, hydroxy, nitro, cyano, amino, alkyl, cycloalkyl, cycloalkenyl, alkoxy, acyl, thio, thioalkyl, alkenyl, alkynyl, cycloalkenyl, heterocyclyl, aryl, or heteroaryl at a first temperature to form a reaction mixture; and

heating the reaction mixture at a second temperature for at least an hour, wherein the second temperature is the same as or different from the first temperature; and

forming at least a first shell over at least a portion of the cores, the shell comprising a semiconductor material.

In certain embodiments, isolating the cores from the growth medium can be preferred before the step of forming the first shell.

Isolating the cores from the growth medium is particularly preferred before forming a first shell comprising cadmium selenide over an indium arsenide core prepared using tris(trimethylgermyl)arsine as the X-donor.

The compound of formula (I) can be tris(trimethylgermyl)nitride; tris(trimethylstannyl)nitride; tris(trimethylplumbyl)nitride; tris(trimethylgermyl)phosphide; tris(trimethylstannyl)phosphide; tris(trimethylplumbyl)phosphide; tris(trimethylgermyl)arsine; tris(trimethylstannyl)arsine; tris(trimethylplumbyl)arsine; tris(trimethylgermyl)stibine; tris(trimethylstannyl)stibine; or tris(trimethylplumbyl)stibine.

Group V (also referred to herein as Group VA) elements include, for example, nitrogen, phosphorus, arsenic, antimony, and bismuth.

In certain embodiments, X can be As. Y can be Ge. Each R, independently, can be alkyl, cycloalkyl, or aryl. Each R, independently, can be unsubstituted alkyl, unsubstituted cycloalkyl, or unsubstituted aryl.

An X donor can further be included in a solvent before being contacted with an M-precursor. In certain embodiments, a solvent can comprise a coordinating solvent or a weakly coordinating solvent. In certain embodiments, a solvent comprises a non-coordinating solvent. A solvent can also comprise a mixture of solvents

In certain preferred embodiments, M included in the M-precursor includes can be a group III element. In certain embodiments, an M-precursor wherein M includes indium can be more preferred.

Examples of M-precursors include, for example, elements, covalent compounds, ionic compounds, and/or coordination complexes, that serve as a source for the desired metal element(s) in the resulting nanocrystal. For example, a metal precursor can constitute a wide range of substances, including, but not limited to, a metal oxide, a metal carbonate, a metal bicarbonate, a metal sulfate, a metal sulfite, a metal phosphate, metal phosphite, a metal halide, a metal carboxylate, a metal alkoxide, a metal thiolate, a metal amide, a metal imide, a metal alkyl, a metal aryl, other organometallics, a metal coordination complex, a metal solvate, and the like. For example, non-limiting examples of indium precursors include In(III) acetate, In(III) trifluoroacetate, trialkyl indium (InR₃)(wherein R=methyl, ethyl, propyl, butyl, pentyl, hexyl, isopropyl, isobutyl, tert-butyl, etc.); non-limiting examples of gallium precursors include Ga(III) acetate, Ga(III) trifluoroacetate, trialkyl gallium (InR₃)(wherein R=methyl, ethyl, propyl, butyl, pentyl, hexyl, isopropyl, isobutyl, tert-butyl, etc.). Other Group III metal precursors can be readily ascertained by one of ordinary skill in the art.

An M-precursor can further be included in a solvent before being contacted with an X donor. In certain embodiments, a solvent can comprise a coordinating solvent or a weakly coordinating solvent. In certain embodiments, a solvent comprises a non-coordinating solvent. A solvent can also comprise a mixture of solvents.

In certain embodiments, the reaction mixture can further include one or more additional solvents.

Examples of solvents include, but are not limited to, octadecene, squalene, methyl myristate, octyl octanoate, hexyl octanoate, and CH₃(CH₂)ₙC(O)O(CH₂)ₘCH₃ wherein n=4-18 and m=1-8, dioctyl ether, and diphenyl ether, and mixtures of one or more solvents. In certain embodiments, a mixture can comprise a mixture, (including but not limited to a eutectic mixture) of biphenyl and diphenyl oxide, including, e.g., DOWTHERM A, available from the Dow Chemical Company. Other high boiling point ethers (e.g., BP >˜200° C.) may also be used. Such ethers (coordinating) can be aromatic ethers, aliphatic ethers or aromatic aliphatic ethers. Examples of additional ethers include, but are not limited to, dihexyl ether, diethyleneglycol dimethyl ether, diethyleneglycol dibutyl ether, triethyleneglycol dimethyl ether, tetraethyleneglycol dimethyl ether, butyl phenyl ether, benzyl phenyl ether, dibenzyl ether, ditolyl ether and isomers thereof. Mixtures of two or more solvents can also be used. Other coordinating solvents can be readily ascertained by one of ordinary skill in the art.

Examples of other non-coordinating solvents that may be useful include, but are not limited to, squalane, octadecane, or any other saturated hydrocarbon molecule. Mixtures of two or more solvents can also be used.

Other solvents for use in the methods taught herein can be readily ascertained by one of ordinary skill in the art.

In certain embodiments, the first temperature is less than 300° C. For example, the first temperature can be in a range from about 80° C. to about 285° C. Other temperatures may be determined to be useful or desirable.

The second temperature can be the same as the first temperature or different. In certain embodiments, for example, the second temperature can be in a range from about 260° C. to about 285° C. Other temperatures may be determined to be useful or desirable.

In certain embodiment, heating at the second temperature can be carried out for up to 2 hours, up to 2.5, hours, up to 3 hours, up to 3.5 hours. Other times within these ranges or outside of these ranges may also be useful.

A semiconductor material included in a shell can comprise an element, for example, a Group IVA element. A semiconductor material included in the shell can comprise a compound represented by the formula MX. In certain examples M comprises, for example, one or more elements from Group IA element (for example, lithium, sodium, rubidium, and cesium), Group IIA (for example, beryllium, magnesium, calcium, strontium, and barium), Group IIB (for example, Zn, Cd, and Hg), Group IIIA (for example, Al, Ga, In and Tl), Group IVA (for example, Si, Ge, Sn, and Pb), and/or the transition metals (for example, Ti, Zr, Hf, V, Nb, Ta, Cr, Mo, W, Mn, Tc, Re, Fe, Co, Ni, Pd, Pt, Rh, and the like). (See, F. A. Cotton et al., Advanced Inorganic Chemistry, 6th Edition, (1999). In certain examples, X comprises one or more elements from Group VA (for example, nitrogen, phosphorus, arsenic, antimony, and bismuth) and/or Group VIA (for example, oxygen, sulfur, selenium, and tellurium). In certain embodiments, a semiconductor material included in the shell comprises a binary (including two elements) material, a ternary (including three elements) material, a quaternary (including four elements) material, etc. In certain embodiments, the material can comprise an alloy and/or a mixture.

Non-limiting examples of a binary semiconductor material that can be included in a shell include ZnS, ZnSe, ZnTe, CdS, CdSe, CdTe, HgS, HgSe, HgTe (IIB-VIA materials), PbS, PbSe, PbTe (IVA-VIA materials), AlN, AlP, AlAs, AlSb, GaN, GaP, GaAs, GaSb, InN, InP, InAs, InSb (IIIA-VA materials). Non-limiting examples of ternary semiconductor materials that can be included in the shell include AₓB_{y}C wherein A may comprise a Group IIB, IIIA or IVA element, B may comprise a group IIB, IIIA, or IVA element, and C may comprise a group VA or VIA element, and x and y are molar fractions between 0 and 1. Preferably x+y=1.

In certain preferred embodiments, the semiconductor material included in the first shell comprises a Group II-VI semiconductor. Examples of a Group II-VI semiconductor include, but are not limited to, CdSe, ZnSe, etc. In certain embodiments, ZnSe can be more preferred.

In certain embodiments, the method can further comprise forming a second shell over the first shell. The second shell can comprise a semiconductor material. In certain embodiments, a Group II-VI semiconductor can be preferred. In certain embodiments, CdZnS can be more preferred.

Shells can be formed on semiconductor nanocrystals by introducing shell precursors at a temperature where material adds to the surface of existing nanocrystals.

Shell thickness can be varied by growing a desired thickness of the shell. For example, the shell can have a thickness less than about one monolayer, about one monolayer, or more than about one monolayer. Preferably, the thickness is less than that at which quantum confinement is not achieved. The thickness is selected to achieve the predetermined characteristics of the core/shell nanocrystal. In certain embodiments, the thickness is in the range from greater than about 0 to about 20 monolayers. In certain embodiments, the thickness is in the range from greater than about 0 to about 10 monolayers. In certain embodiments, the thickness is in the range from greater than about 0 to about 5 monolayers. In certain embodiments, the thickness is in the range from about 1 to about 5 monolayers. In certain embodiments, the thickness is in the range from about 3 to about 5 monolayers. In certain embodiments, more than 20 monolayers can be grown. The actual monolayer thickness is dependent upon the size and composition of the molecules included in the shell.

In preparing a shell, use of a coordinating solvent can be desirable. A coordinating solvent is a compound having at least one donor site (e.g., a lone electron pair) that, for example, is available to coordinate to a surface of the growing nanocrystal. Solvent coordination can stabilize the growing nanocrystal. Examples of coordinating solvents include alkyl phosphines, alkyl phosphine oxides, alkyl phosphonic acids, or alkyl phosphinic acids, however, other coordinating solvents, such as pyridines, furans, and amines may also be suitable for the nanocrystal production. More specific examples of suitable coordinating solvents include pyridine, tri-n-octyl phosphine (TOP), tri-n-octyl phosphine oxide (TOPO) and trishydroxylpropylphosphine (tHPP). Technical grade TOPO can be used. Alternatively, a non-coordinating solvent could be used. Examples of non-coordinating solvents include saturated hydrocarbons; other examples are provided elsewhere herein.

The present invention will be further clarified by the following non-limiting examples, which are intended to be exemplary of the present invention.

### EXAMPLES

### Example 1

Three different methods for preparing an indium arsenide semiconductor nanocrystal are described below.

In each of the following three methods, tris(trimethylgermyl) arsine is used as the X-donor. Method A:
1. In two 100 milliliter (mL) round bottom flasks, degas 10 mL 1-octadecene (ODE) at 80° C. for 1 hour.
2. Refill with N₂ and Inject:
   4 mL indium myristate (InMyr) (0.25M in ODE, 10 mmol)
3. Heat the reaction vessel to 280° C. and inject:
   214 mg tris (trimethylgermyl) arsine (As(TMG)₃) (0.5mmol) diluted to 1 mL with ODE.
4. Heat at 260° C. for 2.5 hours.
5. Cool to room temperature and cannula transfer to glovebox for purification.
   Purification: Split the reaction solution into 2 centrifuge tubes, and fill to the 45mL line with 5:1 butanol:methanol (BuOH:MeOH) to induce precipitation. Vortex to mix, then spin at max (4200 rpm) for 3 minutes. Discard supernatant and redisperse cores in 10 mL of hexane. Filter through black and red filters.

### Method B:

1. To 100 mL round bottom flask:
   30 mL 1-octadecene (ODE)
   1.35g stearic acid
2. Degas at 80° C. until vacuum gauge reads below 100 mTorr (typically 1 hour).
3. Prepare in glovebox:
   300 mg trimethyl indium (TMI) in 3 mL eutectic mixture of diphenyl ether and biphenyl (DTA)
   402 mg tris (trimethylgermyl) arsine (As(TMG)₃) in 1.5 mL ODE
   0.9 ml Dioctyl amine (DOA), neat
4. Inject as follows:
   tris (trimethylgermyl) arsine (As(TMG)₃), stir for 1 minute.
   DOA, stir for 1 minute.
   TMI, stir for 28 minute. (For a total of 30 minute at 80° C.)
5. Ramp temperature to 265° C. and stir for 2 hours.
6. Cool to room temperature and cannula transfer to glovebox for purification.
   Purification: Split the reaction solution into 3 centrifuge tubes, and fill to the 45 mL line with 5:1 butanol:methanol (BuOH:MeOH) to induce precipitation. Vortex to mix, then spin at max (4200 rpm) for 3 minutes. Discard supernatant and redisperse cores in 20 mL of hexane. Filler through black and red filters.

### Method C:

1. To a 100.0 mL round bottom flask, equipped with TALL condenser, in the glove box, add:
   1.20 g of 2,3-dimethyl phenol (9.8 mmol)
   1.35 g of myristic acid (5.9 mmol)
2. Add 10.0 mL of squalane and degas for 1 hour at 80° C.
3. Return round bottom flask to N₂ and use heat gun to melt any sublimated phenol back into the reaction flask.
4. Ramp temp to 180° C. and prepare precursor injection:
   0.271 g trimethyl indium (TMI) (FW 159.93 g/mol, 1.7 mmol)
   0.481 g dioctyl amine (DOA) (FW 241.46 g/mol, 2 mmol)
   1 mL eutectic mixture of diphenyl ether and biphenyl (DTA)0.381 g tris (trimethylgermyl) arsine (As(TMG)₃) (0.89 mmol)
5. Turn stirring on high, inject precursors, ramp temp to 285° C. and stir for 3 hours
6. Cool to room temperature and cannula transfer to glovebox for purification.
   Purification: Split the reaction solution into 2 centrifuge tubes, and fill to the 45 mL line with 5:1 butanol:methanol (BuOH:MeOH) to induce precipitation. Vortex to mix, then spin at max (4200 rpm) for 3 minutes. Discard supernatant and redisperse cores in 20 mL of hexanes. Filter through black and red filters.

Each of the above three methods was also carried out, but substituting an equal molar quantity of tris (trimethylsilyl) arsine, for the tris (trimethylgermyl)arsine.

Table 1 below shows a comparison of first exciton absorption for InAs cores synthesized by above three methods with either TMS-As or TMGe-As as the X-donor.

TABLE 1

| | | | Abs | HWHM |
|---|---|---|---|---|
| Sample | Method | As Source | [nm] | [NM] |
| S101-049A | A | TMS-As | 701 | 107 |
| S101-042A | A | TMGe-As | 715 | 54 |
| S101-032A | B | TMS-As | 738 | 55 |
| S101-052A | B | TMGe-As | 700 | 41 |
| S101-065A | C | TMS-As | 846 | 54 |
| S101-065B | C | TMGe-As | 821 | 63 |

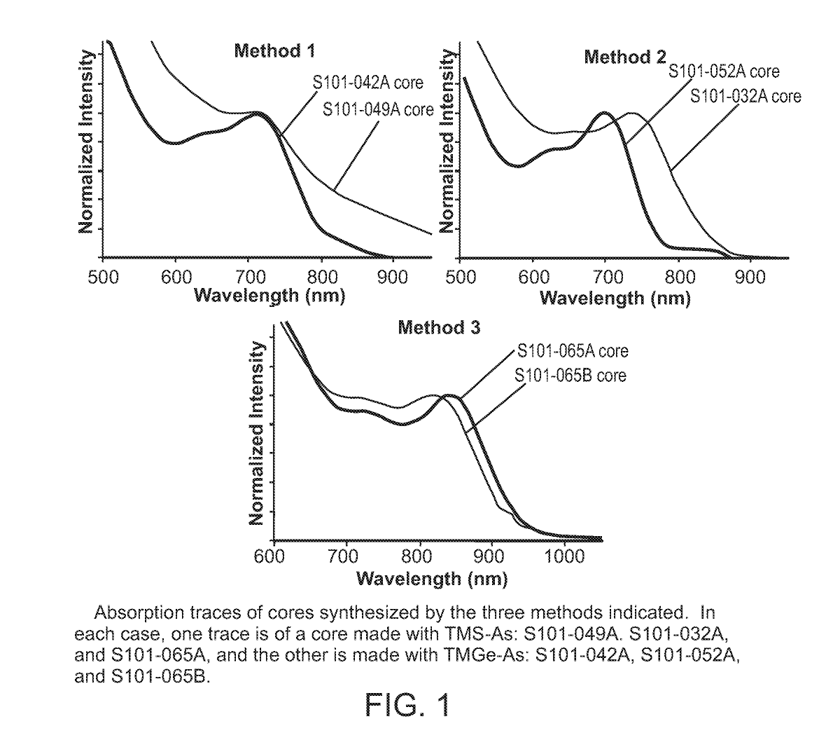

FIG. 1 shows the absorption traces of cores syntheized by the above three methods. In each case, one trace is for a core made with tris(trimethylsilyl) arsine (TMS-As): S101-49A, S101-032A, and S101-065A; and the other trace is for a core made with tris (trimethylgermyl) arsine (TMGe0As): S101-042A, S101-052A, and S101-065B.

### Example 2

When an InAs core made with use of tris (trimethylgermyl) arsine as the X-donor was overcoated with a CdSe first shell in situ in the growth medium (e.g., without being isolated from the growth medium before the coating step), no first exciton absorption feature could be detected in the final InAs/CdSe/CdZnS core/shell/shell material.

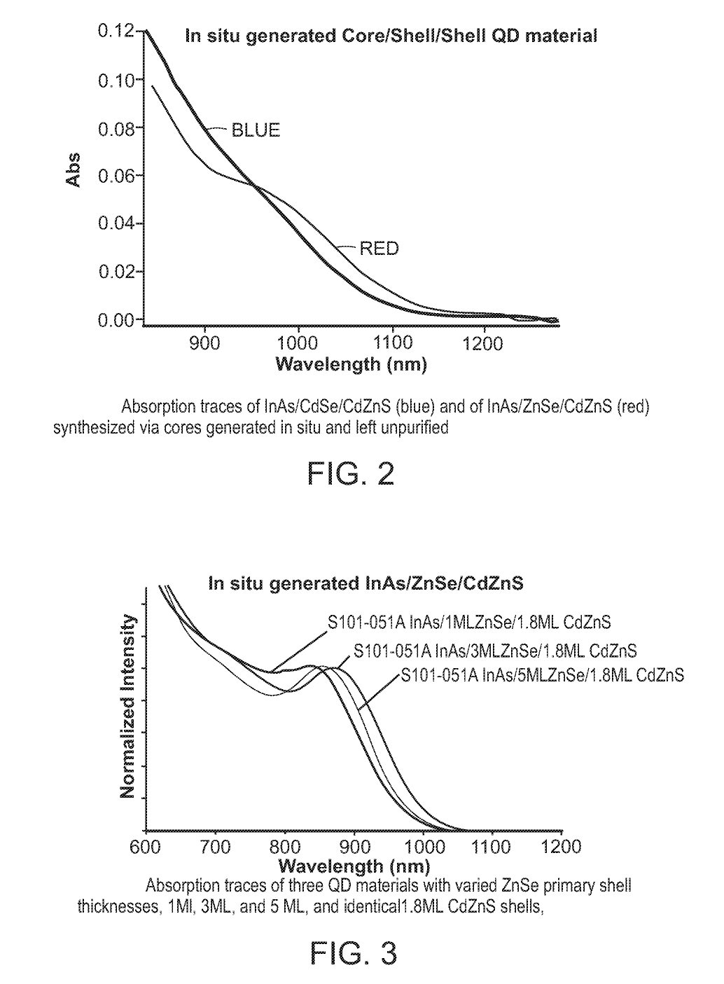

However, with use of a ZnSe first shell on isolated InAs core made with use of tris (trimethylgermyl) arsine as the X-donor, the absorption features were maintained. See FIG. 2, which shows absorption traces of InAs/CdSe/CdZnS and of InAs/ZnSe/CdZnS synthesized via cores generated in situ and left unpurified.

Further, as the thickness of the ZnSe primary shell is increased, the first exciton peaks become more well-defined and undergo less of a redshift. See, for example, FIG. 3.

FIG. 3 shows absorption traces of three quantum dot materials which include an in situ generated InAs core, in accordance with the present invention, with varied ZnSe primary shell thicknesses, 1 monolayer (ML), 3 ML, and 5ML, and identical 1.8 ML CdZnS shells. These three quantum dot materials are designated in FIG. 3 as: S101-51A InAs/1M: ZnSe/1.8 ML CdZnS; S101-51A InAs/3M: ZnSe/1.8 ML CdZnS; and S101-51A InAs/5M: ZnSe/1.8 ML CdZnS, respectively. Addition of the secondary CdZnS shell causes a redshift that is independent of the thickness of the secondary shell.

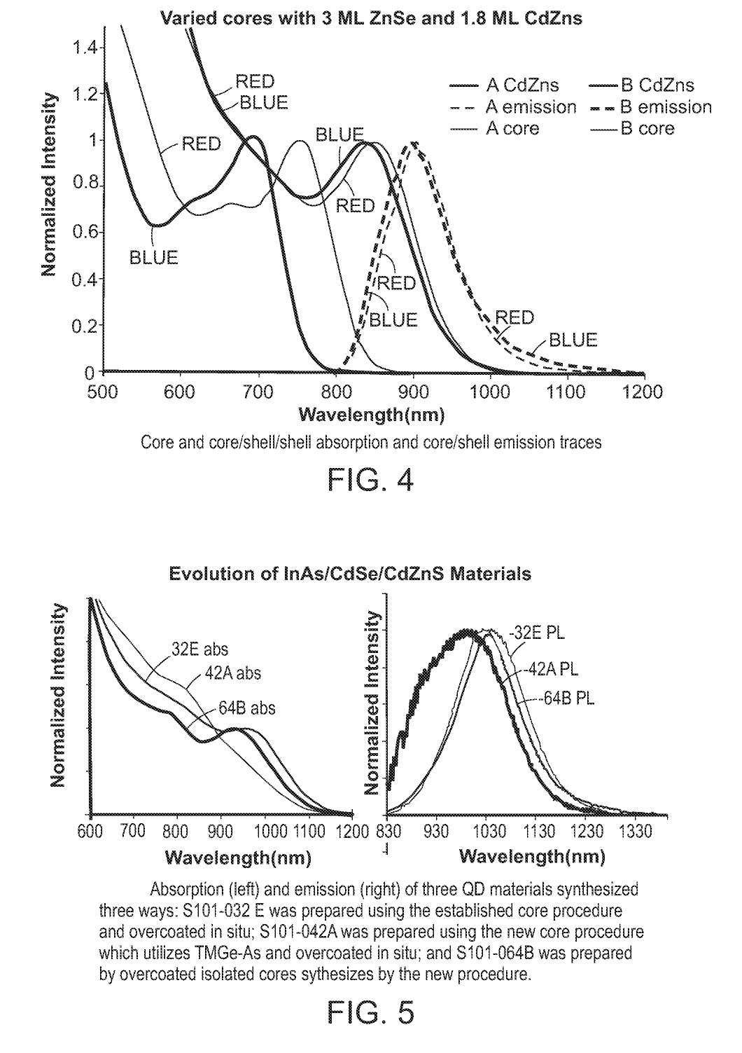

FIG. 4 shows core and core/shell/shell absorption and core/shell/shell emission traces for two cores prepared in accordance with an embodiment of the present invention, with Initial (first exciton) absorption at 700 nm (designated in FIG. 4 by A, blue) and 750 nm (designated in FIG. 4 by B, red), respectively, overcoated identically with a 3 ML ZnSe primary shell and a 1.8 ML CdZnS secondary shell. The absorption of the cores and final QD materials (solid traces) as well as the emission of the final QD materials (dashed traces) are shown. In this case, the resulting QD materials were nearly identical despite the 50 nm difference in core absorption (FIG. 4). This is in direct opposition to the trends observed when using a CdSe primary shell. In that case, an increasing red shift with redder InAs cores, thicker CdSe shells, and thicker CdZnS secondary shells is observed. This trend is consistent with ZnSe confining the first exciton to the InAs core more effectively than CdSe in the same system. Similar results are seen in InAs/ZnSe/CdZnS materials synthesized both in situ and from isolated and purified cores.

Example core/shell/shall procedure beginning with an isolated core:
1. Degas 3 mL of 1-octadecene (ODE) for 30 minutes at 70° C. Inject:
   0.46 mL cores (crashed core In hexane (See sample S101. 065B in Table 1 above) abs 821 nm) In
   3 mL ODE and vacuum for 1 hour to remove hexane.
2. Meanwhile, charge a 100 mL. round bottom with:
   1.35 mL Zn(oleate) (0.5 M in trioctylphosphine (TOP)
   10 mL squalene (SQ)
   and degas at 115° C. for 1 hour.
3. Set up syringes for overcoats:

Primary Shell:
0.41 mL DIBP-Se, 1M in 1-dodecyl-2-pyrrolidinone (NDP)

Secondary Shell, 2 syringes:
A: 0.27 mL cadmium(oleate), 1M in TOP
   0.54 mL zinc(oleate), 0.5M In TOP
   Dilute with TOP to 1 mL
B: 0.39 mL 1-dodecanethiol (DDT)
   Dilute with 1-octadecene (ODE) to 1 mL
4. Set the temperature to ramp to 320° C. and charge core at 315° C. Set temperature to 300° C. for addition.
5. Start Primary Shell addition immediately after charging the core with a rate of 0.55 mL/hour for a 45 minute total addition time.
6. After 45 minutes, switch to the Secondary Shell injection. Set the temperature to 315° C. and begin injection with a rate of 1 mL/hour for a total 1 hour addition time.
7. Cool the reaction to room temperature and cannula transfer to the glovebox for purification.

Purification: Split the reaction solution into 2 centrifuge tubes, and fill to the 45 mL line with 5:1 butanol:methanol (BuOH:MeOH) to induce precipitation. Vortex to mix, then spin at max (4200 rpm) for 3 minutes. Discard supernatant and redisperse cores in 2 mL of hexane per tube. Fill again to the 45 mL line with 5:1 BuOH:MeOH to induce precipitation. Discard supernatant and redisperse cores in 5mL of hexanes. Filter through black and red filters.

### Example 3

InAs cores made with use of tris (trimethylsilyl) arsine (TMS-As) as the X-donor and overcoated in situ with CdSe and CdZnS maintained well-defined and relatively narrow first exciton absorption features. As discussed above, when an InAs core made with use of tris (trimethylgermyl) arsine as the X-donor was overcoated with a CdSe and CdZnS in situ, no first exciton absorption feature could be detected in the final InAs/CdSe/CdZnS core/shell/shell material.

When the core is isolated and purified before overcoating, the absorption features were maintained and the overall performance of the QD material was enhanced (See FIG. 5 and Table 2).

FIG. 5 shows absorption (left graph) and emission (PL) (right graph) traces for three quantum dot materials synthesized three ways: S101-032E (designated in FIG. 5 as “32E”) prepared using the established core procedure (using an X donor=TMS-As) and overcoated in situ; S101-042A (designated in FIG. 5 as “42A”) prepared with use of an X-donor=TMGe-As, wherein the core is overcoated in situ; and S101-064B (designated in FIG. 5 as “64B”) prepared by overcoating isolated cores synthesized by with use of an X-donor=TMGe-As.

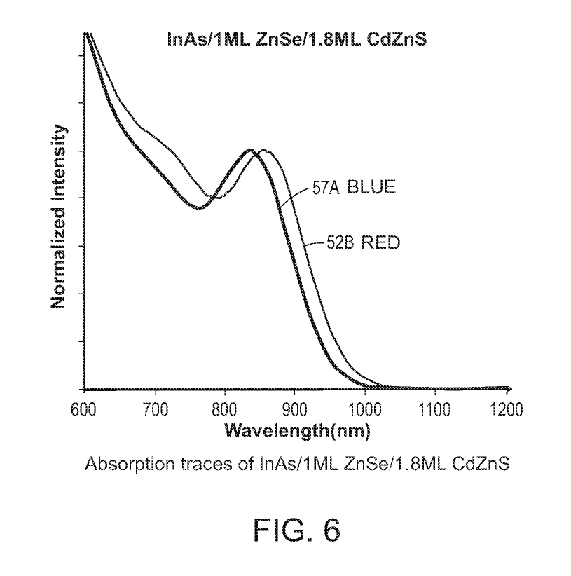

When the CdSe shell is replaced by a ZnSe primary shell, the trend is also seen but is less pronounced. See FIG. 6. FIG. 6 shows absorption traces for InAs/1ML ZnSe/1.8ML CdZnS synthesized via an in situ method (designated in FIG. 6 as 52B, “RED”) and from an isolated and purified core (designated in FIG. 6 as 57A, “BLUE”).

Example core purification procedure:
1. Cannula transfer room temperature crude core solution to the glovebox.
2. Divide the solution among centrifuge tubes such that each tube has 10-15 mL of crude core solution, and fill to the 45 mL line with 5:1 butanol:methanol (BuOH:MeOH) to induce precipitation.
3. Vortex to mix, then spin at max (4200 rpm) for 3 minutes.
4. Discard supernatant and redisperse cores in about 3 mL of hexanes per tube.
5. Filter through black and red filters.
   Example overcoat of purified cores procedure:
1. Degas 5 mL 1-octadecene (ODE) at 70° C. for 30 minutes and inject:
   2.47 mL InAs (cores in hexane, 0.165 mmol, [In]: 33 mM)
   Degas for an additional hour at 70° C. to fully remove the hexane.
2. Set the temperature to 180° C. and prepare two precursor syringes for primary shell injection:
   Syringe 1:
   0.5 M CadmiumOleate
   0.22 mL
   Dilute with TOP to 1.5 L
   Syringe 2:
   1 M diisobutylphosphine selenide (DiBP-Se) (in TOP) 0.22 mL
   Dilute with TOP to 1.5 mL
   At 180° C. begin the injection, rate 1.5 mL/hr while the solution is stirred under N₂. The injection was complete in 1 hour.
3. Prepare two precursor syringes for secondary shell overcoat:

Syringe 1:
Cadmium oleate (1M) 72 ml
Zinc oleate (0.5M) 1.38 mL
Dilute with TOP to 3 mL
Syringe 2:
1-dodecanethiol (DDT) 0.99 mL
Dilute with ODE to 3 mL
Begin injection at 180° C., rate 2 mL/hr, and immediately ramp the temperature to 315° C. The injection was complete in 1.5 hours.
4. Cool to room temperature and cannula transfer to glovebox for purification.
   Purification:
   Split the reaction solution into 2 centrifuge tubes, and fill to the 45 mL line with 2:1 BuOH:MeOH to induce precipitation. Vortex to mix, then spin at max (4200 rpm) for 3 minutes. Discard supernatant and redisperse cores In 2 mL of hexanes per tube. Fill to 45 mL line with 1:1 MeOH:BuOH to induce precipitation again. Vortex to mix, then spin at max (4200 rpm) for 3 minutes. Discard supernatant and redisperse cores in 6 mL of hexane. Filter through black and red filters.

TABLE 2
Properties And Solution Performance Of QD Materials
Made From Isolated And In Situ Cores.

| | | Core | Core | | ML | | | | | |
|---|---|---|---|---|---|---|---|---|---|---|
| | Core | abs | HWHM | ML | CdZ | PL | FWHM | Abs | HWHM | QY |
| Sample | method | (nm) | (nm) | CdSe | nS | (nm) | (nm) | (nm) | (nm) | (%) |
| S101-032E | In situ, old | 724 | 50 | 1 | 3 | 1040 | 160 | 955 | 90 | 42.2 |
| | core | | | | | | | | | |
| | (X donor = | | | | | | | | | |
| | TMS-As) | | | | | | | | | |
| S101-042A | In situ, new | 715 | 54 | 0.3 | 1.8 | 984 | 224 | . . . | . . . | 29.2 |
| | core | | | | | | | | | |
| | (X donor = | | | | | | | | | |
| | TMGe-As) | | | | | | | | | |
| S101-064B | Isolated, new | 691 | 39 | 1 | 3 | 1024 | 149 | 928 | 98 | 95.5 |
| | core | | | | | | | | | |
| | (X donor = | | | | | | | | | |
| | TMGe-As) | | | | | | | | | |

In accordance with another aspect of the present invention, there is provided a semiconductor nanocrystal including a core comprising indium arsenide, a first shell comprising zinc selenide, and a second shell comprising a second semiconductor material.

In certain embodiments, the second shell comprises a Group II-VI semiconductor.

In certain embodiments, the second shell comprises cadmium, zinc, and selenium.

Semiconductor nanocrystals typically have ligands attached thereto. Ligands can be derived from a coordinating solvent that may be included in the reaction mixture during the growth process. Ligands can also be added to the reaction mixture. Ligands can also be derived from a reagent or precursor including in the reaction mixture for preparing or overcoating the semiconductor nanocrystals. In certain embodiments, more than one type of ligand can be attached to an outer surface of a nanocrystal.

Additional information that may be useful with the present invention is included in International Publication No. WO/2013/040365 of MIT, for “Highly Luminescent Semiconductor Nanocrystals”, published 21 Mar. 2013; International Application No. PCT/US2009/004345, of Breen, et al for “Nanoparticle Including Multi-Functional Ligand And Method”, filed 28 Jul. 2009, International Application No. PCT/US2007/024320, of Clough, et al.,for “Nanocrystals Including A Group III A Element And A Group V A Element, Method, Composition, Device And Other Products”, filed 21 Nov. 2007, International Publication No. WO 2012/099653 of QD vision, Inc., for “Semiconductor Nanocrystals And Methods Of Preparation” published 26 Jul. 2012; International Publication No. WO 2013/173409 A1 of QD Vision, Inc. for “Semiconductor Nanocrystals And Methods Of Preparation”, published 21 Nov. 2013; International Application No. PCT/US2007/13152 of Coe-Sullivan, et al., for “Light-Emitting Devices and Displays With Improved Performance”, filed 4 Jun. 2007; and U.S. Ser. No. 12/283,609 of Coe-Sullivan, et al. for “Compositions, Optical Component, System Including An Optical Component, Devices, And Other Products”, filed 12 Sep. 2008. The disclosures of each of the foregoing applications are hereby incorporated herein by reference in their entireties.

As used herein, the singular forms “a”, “an” and “the” include plural unless the context clearly dictates otherwise. Thus, for example, reference to an emissive material includes reference to one or more of such materials.

The entire contents of all patent publications and other publications cited in this disclosure are hereby incorporated herein by reference in their entirety. Further, when an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1-5. (canceled)

6. A method for preparing a semiconductor nanocrystal including a core comprising a Group III element and a Group V element and a shell over at least a portion of the core, the method comprising: contacting an M-precursor compound with an X donor, wherein the X donor is represented by the formula (I):
X(Y(R)₃)₃ (I)
in a reaction mixture, where X is a group V element; Y is Ge, Sn, or Pb; and each R, independently, is alkyl, alkenyl, alkynyl, cycloalkyl, cycloalkenyl, heterocyclyl, aryl, or heteroaryl, wherein each R, independently, is optionally substituted by 1 to 6 substituents independently selected from hydrogen, halo, hydroxy, nitro, cyano, amino, alkyl, cycloalkyl, cycloalkenyl, alkoxy, acyl, thio, thioalkyl, alkenyl, alkynyl, cycloalkenyl, heterocyclyl, aryl, or heteroaryl at a first temperature to form a reaction mixture;
heating the reaction mixture at a second temperature for at least an hour, wherein the second temperature is the same as or different from the first temperature;
isolating cores from the reaction mixture after heating; and
forming at least a first shell over at least a portion of the isolated cores, the shell comprising a semiconductor material.

7. A method in accordance with claim 6 wherein the compound of formula (I) comprises tris(trimethylgermyl)arsine.

8. A method in accordance with claim 6 wherein M comprises a Group III element.

9. A method in accordance with claim 6 wherein M comprises indium.

10. A method in accordance with claim 6 wherein the semiconductor nanocrystals comprise indium arsenide.

11. A method in accordance with claim 6 wherein the semiconductor material comprises a Group II-VI compound.

12. A method in accordance with claim 6 wherein the semiconductor material comprises cadmium selenide.

13. A method in accordance with claim 6 wherein the semiconductor material comprises zinc selenide.

14. A method in accordance with claim 6 wherein the method further comprises forming a second shell over the first shell.

15. A method in accordance with claim 14 wherein the second shell comprises a second semiconductor material.

16. (canceled)

17. (canceled)

18. A method for preparing a semiconductor nanocrystal including a core comprising a Group III element and a Group V element and a shell over at least a portion of the core, the method comprising: contacting an M-precursor compound with an X donor, wherein the X donor is represented by the formula (I):
X(Y(R)₃)₃ (I)
in a reaction mixture, where X is a group V element; Y is Ge, Sn, or Pb; and each R, independently, is alkyl, alkenyl, alkynyl, cycloalkyl, cycloalkenyl, heterocyclyl, aryl, or heteroaryl, wherein each R, independently, is optionally substituted by 1 to 6 substituents independently selected from hydrogen, halo, hydroxy, nitro, cyano, amino, alkyl, cycloalkyl, cycloalkenyl, alkoxy, acyl, thio, thioalkyl, alkenyl, alkynyl, cycloalkenyl, heterocyclyl, aryl, or heteroaryl at a first temperature to form a reaction mixture;
heating the reaction mixture at a second temperature for at least an hour, wherein the second temperature is the same as or different from the first temperature;
and
forming at least a first shell over at least a portion of the cores in the reaction mixture, the shell comprising a semiconductor material.

19. A method in accordance with claim 18 wherein the compound of formula (I) comprises tris(trimethylgermyl)arsine.

20. A method in accordance with claim 18 wherein M comprises a Group III element.

21. A method in accordance with claim 18 wherein M comprises indium.

22. A method in accordance with claim 18 wherein the semiconductor nanocrystals comprise indium arsenide.

23. A method in accordance with claim 18 wherein the semiconductor material comprises a Group II-VI compound.

24. A method in accordance with claim 18 wherein the semiconductor material comprises cadmium selenide.

25. A method in accordance with claim 18 wherein the semiconductor material comprises zinc selenide.

26. A method in accordance with claim 18 wherein the method further comprises forming a second shell over the first shell.

27. A method in accordance with claim 26 wherein the second shell comprises a second semiconductor material.

28-32. (canceled)
